(19) United States
(12) Patent Application Publication
(10) Pub. No.: US 2012/0138976 A1
(43) Pub. Date: Jun. 7, 2012

(54) ORGANIC ELECTROLUMINESCENT ELEMENT, ORGANIC ELECTROLUMINESCENT DISPLAY DEVICE, AND ORGANIC ELECTROLUMINESCENT ILLUMINATING DEVICE

(76) Inventor: Yoshimasa Fujita, Osaka (JP)

(21) Appl. No.: 13/390,376

(22) PCT Filed: Apr. 15, 2010
(86) PCT No.: PCT/JP2010/002731

§ 371 Date: Feb. 14, 2012

(51) Int. Cl. H01L 33/36; H01L 27/15

(52) U.S. Cl. 257/88; 257/99; 257/40; 257/E33.062; 257/E27.12

(57) ABSTRACT

An organic electroluminescent element according to the present invention includes: an anode (3); a cathode (4); and an organic light-emitting layer (7) sandwiched between the anode (3) and the cathode (4), the organic light-emitting layer (7) including a hole transporting light-emitting layer (5) and an electron transporting light-emitting layer (6), the hole transporting light-emitting layer (5) being located closer to the anode (3) than the electron transporting light-emitting layer (6), containing a hole transporting material, and including an acceptor region doped with an acceptor and a first light-emitting dopant region doped with a first light-emitting dopant, the acceptor region being located on that side of the hole transporting light-emitting layer (5) which faces the anode (3), and the first light-emitting dopant region being located on that side of the hole transporting light-emitting layer (5) which faces the cathode (4), the electron transporting light-emitting layer (6) being located closer to the cathode (4) than the hole transporting light-emitting layer (5), containing an electron transporting material, and including a donor region doped with a donor and a second light-emitting dopant region doped with a second light-emitting dopant, the donor region being located on that side of the electron transporting light-emitting layer (6) which faces the cathode (4), and the second light-emitting dopant region being located on that side of the electron transporting light-emitting layer (6) which faces the anode (3). This makes it possible to provide a simple-structured, high-luminance, high-efficiency, and long-life organic EL element.

### TECHNICAL FIELD

The present invention relates to an organic electroluminescent element that achieves high luminance, high efficiency, and long life with a simple structure, an organic electroluminescent display device including such an organic electroluminescent element, and an organic electroluminescent illuminating device including such an organic electroluminescent element.

### BACKGROUND ART

Along with the recent development of advanced information society, there has been a growing need for flat-panel displays. Known examples of flat-panel displays include non-self-light-emitting liquid crystal displays (LCDs), self-light-emitting plasma displays (PDP), inorganic electroluminescent (inorganic EL) displays, and organic electroluminescent (hereinafter referred to as “organic EL” or “organic LED”) displays, etc. Among these flat-panel displays, organic electroluminescent displays have made notable progress.

Improvements in materials and multilayering of device structures have so far been made for improving the luminous efficiency and life of organic EL displays. In particular, a multilayer structure shown in FIG. 2 is presently available for the realization of high-efficiency and long-life organic EL elements with use of phosphorescent materials. This multilayer structure includes an anode 12, a cathode 19, and six layers sandwiched between the anode 12 and the cathode 19. The six layers are a hole injection layer 13, a hole transport layer 14, a light-emitting layer 15, a hole blocking layer 16, an electron transport layer 17, and an electron injection layer 18. FIG. 2 is a schematic view showing a configuration of a conventional organic electroluminescent element.

Meanwhile, Non-patent Literature 1 discloses an organic EL element having a simple structure called “homo junction” made with a bipolar material that exhibits high charge mobility. FIG. 3 is a schematic view showing a configuration of a conventional organic electroluminescent element.

As shown in FIG. 3, an organic EL element 20 of Non-patent Literature 1 has such a simple structure that a positive and negative charge transporting light-emitting layer 24 containing a positive and negative charge transporting material is sandwiched between an anode 22 provided on a substrate 21 and a cathode 23. Non-patent Literature 1 discloses emitting EL light with both fluorescence and phosphorescence and emitting three primary colors of EL light, namely blue, green, and red EL light, in such a simple-structured organic EL element.

### CITATION LIST

Non-patent Literature 1
Advanced Materials 2009, 21, 1-4
Non-patent Literature 2
APPLIED PHYSICS LETTERS 89,103510 (2006)

### SUMMARY OF INVENTION

### Technical Problem

However, multilayering of the structure of an organic EL element gives rise to problems such as a complication of steps of a manufacturing process and an increase in cost of a manufacturing apparatus.

Further, the organic EL element 40 of Non-patent Literature 1, which has a simple layer structure, undesirably decreases in luminous efficiency or luminance as time passes. This is due to the use of a single host in the positive and negative charge transporting light-emitting layer 24.

That is, in the organic EL element 20, only the positive and negative charge transporting light-emitting layer 24, i.e., a layer in which a single host is used, is formed between the anode 22 and the cathode 23. In this case, holes injected from the anode and electrons injected from the cathode are recombined with each other in the bulk of positive and negative charge transporting light-emitting layer 24. This makes it impossible to bring about a “charge-confining effect” of confining holes and electrons in a light-emitting region. That is, under high luminance (under high electric current), unlike in a case where holes and electrons are confined in a particular space as they would when they are recombined with each other at the interface, there is no confining effect in the bulk. This decreases the probability of holes and electrons being recombined with each other. That is, this increases the probability of holes and electrons reaching the respective counter electrodes (holes reaching the cathode and electrons reaching the anode) without being recombined with each other. This makes it impossible to emit light efficiently, thus making it impossible to emit light at high luminance.

Further, since there is a difference between the rate at which hole mobility decreases and the rate at which electron mobility decreases, an aging process breaks down the balance between holes and electrons, thereby decreasing luminous efficiency. Furthermore, the aging process causes a site of recombination of holes and electrons to move through the bulk. The movement causes a displacement of the light-emitting region as entailed by the recombination of charges. The displacement causes a color shift, thus leading to a decrease in life.

The present invention has been made in view of the foregoing problems, and it is an object of the present invention to provide a simple-structured, high-luminance, high-efficiency, and long-life organic electroluminescent element.

### Solution to Problem

In order to solve the foregoing problems, an organic electroluminescent element according to the present invention includes: an anode; a cathode; and an organic light-emitting layer sandwiched between the anode and the cathode, the organic light-emitting layer including a hole transporting light-emitting layer and an electron transporting light-emitting layer, the hole transporting light-emitting layer being located closer to the anode than the electron transporting light-emitting layer, containing a hole transporting material, and including an acceptor region doped with an acceptor and a first light-emitting dopant region doped with a first light-emitting dopant, the acceptor region being located on that side of the hole transporting light-emitting layer which faces the anode, and the first light-emitting dopant region being located on that side of the hole transporting light-emitting layer which faces the cathode, the electron transporting light-emitting layer being located closer to the cathode than the hole transporting light-emitting layer, containing an electron transporting material, and including a donor region doped with a donor and a second light-emitting dopant region doped with a second light-emitting dopant, the donor region being located on that side of the electron transporting light-emitting layer which faces the cathode, and the second light-emitting dopant region being located on that side of the electron transporting light-emitting layer which faces the anode.

According to the foregoing configuration, the organic electroluminescent element (also hereinafter referred to as “organic EL element”) of the present invention includes the organic light-emitting layer sandwiched between the anode and the cathode, the organic light-emitting layer including the hole transporting light-emitting layer located on the anode and the electron transporting light-emitting layer located on the cathode. Further, that side of the hole transporting light-emitting layer which faces the anode is doped with the acceptor, and that side of the electron transporting light-emitting layer which faces the cathode is doped with the donor.

By thus doping the interface between the organic light-emitting layer and each electrode with the acceptor or with the donor, there is a reduction in width of the energy barrier formed at the interface. The higher the energy barrier is, the more the injection of charges from the electrode is inhibited. Such a reduction in width brings about an improvement in the injection of charges by a tunneling effect through a narrow depletion region (see Non-patent Literature 2). This allows a sufficient increase in charge injection efficiency in that region and therefore makes it unnecessary to provide a hole injection layer or an electron injection layer between each electrode and the organic light-emitting layer.

Furthermore, the carrier concentration is increased by doping the bulk with the acceptor or with the donor. This leads to a big rise in conductivity, thus bringing about a sufficient improvement in charge (hole or electron) conductivity. This is generally known in the field of semiconductors, and is similar to a mechanism by which for a rise to a desired carrier concentration in the case of a semiconductor such as silicon that has high purity and has almost no free electrons, carriers are injected by optionally adding a conductive impurity This makes it unnecessary to provide a hole transport layer or an electron transport layer between each electrode and the organic light-emitting layer for smoothing the transport of charges.

By thus combining the hole transporting light-emitting layer doped with the acceptor and the electron transporting light-emitting layer doped with the donor and emitting light at the respective interfaces, the organic EL element according to the present invention can confine charges and exciters in the interfaces. For this reason, even when the organic EL element is configured to omit hole and electron injection layers and hole and electron transport layers, the organic EL element can keep high-luminance and high-efficiency emission over a long period of time.

Further, in the organic EL element according to the present invention, that side of the hole transporting light-emitting layer which faces the cathode is doped with the first light-emitting dopant, and that side of the electron transporting light-emitting layer which faces the anode is doped with the second light-emitting dopant. That is, an interfacial region of the hole transporting light-emitting layer with the electron transporting light-emitting layer and an interfacial region of the electron transporting light-emitting layer with the hole transporting light-emitting layer, both located in the center of the organic light-emitting layer, are doped with the light-emitting dopants, respectively.

It should be noted that the regions doped with the light-emitting dopants have an effect of confining charges moving through the organic light-emitting layer. Therefore, even if the mobility of holes and the mobility of electrons in the hole transporting light-emitting layer and the electron transporting light-emitting layer 6 are different, it is possible to confine these charges in the light-emitting dopant regions. By thus letting holes and electrons stay at the interfacial regions between the hole transporting light-emitting layer and the electron transporting light-emitting layer, the probability of holes and electrons being recombined with each other can be increased and the balance between charges can be maintained even under high luminance (under high electric current).

Furthermore, even in a case where there occurs a difference in decrease between hole mobility and electron mobility as caused by an aging process, the confinement of changes in the interfacial regions prevents breaking down of the balance between holes and electrons. This prevents a decrease in luminous efficiency and does not cause a color shift that is entailed by a movement of a site of recombination, thus making it possible to extend the life of the organic EL element.

Therefore, the organic EL element of the present invention can keep high-luminance and high-efficiency emission over a long period of time.

In order to solve the foregoing problems, an organic electroluminescent display device according to the present invention include display means including a thin-transistor substrate and an organic electroluminescent element according to the present invention, the organic electroluminescent element being provided on the thin-transistor substrate. Further, an organic electroluminescent illuminating device includes an organic electroluminescent element according to the present invention.

Since the foregoing configuration includes an organic electroluminescent element that is high in charge injection capability and luminous efficiency, the foregoing configuration can provide a high-luminance, high-efficiency, and long-life illuminating device.

### Advantageous Effects of Invention

An organic electroluminescent element according to the present invention includes: an anode; a cathode; and an organic light-emitting layer sandwiched between the anode and the cathode, the organic light-emitting layer including a hole transporting light-emitting layer and an electron transporting light-emitting layer, the hole transporting light-emitting layer being located closer to the anode than the electron transporting light-emitting layer, containing a hole transporting material, and including an acceptor region doped with an acceptor and a first light-emitting dopant region doped with a first light-emitting dopant, the acceptor region being located on that side of the hole transporting light-emitting layer which faces the anode, and the first light-emitting dopant region being located on that side of the hole transporting light-emitting layer which faces the cathode, the electron transporting light-emitting layer being located closer to the cathode than the hole transporting light-emitting layer, containing an electron transporting material, and including a donor region doped with a donor and a second light-emitting dopant region doped with a second light-emitting dopant, the donor region being located on that side of the electron transporting light-emitting layer which faces the cathode, and the second light-emitting dopant region being located on that side of the electron transporting light-emitting layer which faces the anode. This makes it possible to provide a simple-structured, high-luminance, high-efficiency, and long-life organic electroluminescent element.

### BRIEF DESCRIPTION OF DRAWINGS

FIG. 1 is a schematic view showing a configuration of an organic electroluminescent element according to an embodiment of the present invention.

FIG. 2 is a schematic view showing a configuration of a conventional organic electroluminescent element.

FIG. 3 is a schematic view showing a configuration of a conventional organic electroluminescent element.

FIG. 4 is a schematic view showing a configuration of an organic electroluminescent display according to an embodiment of the present invention.

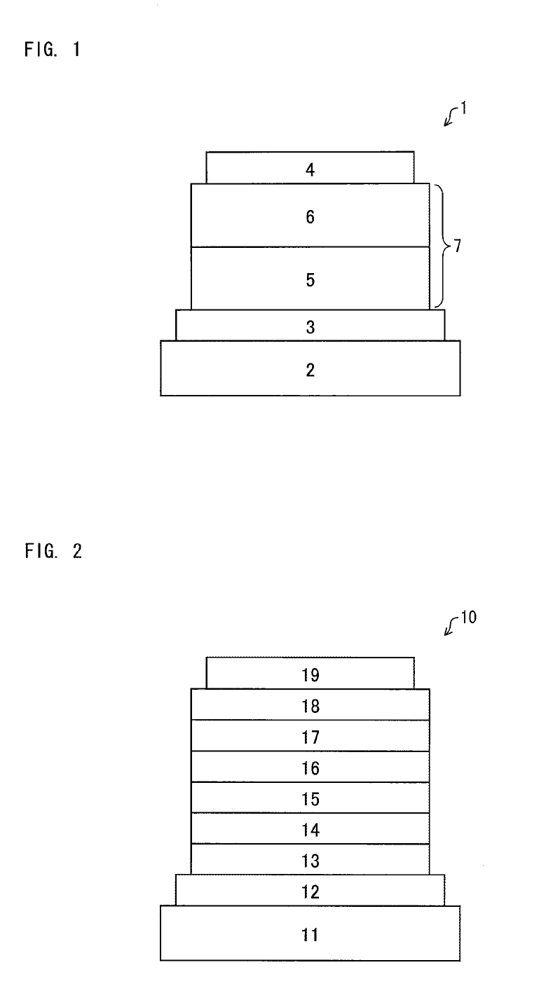

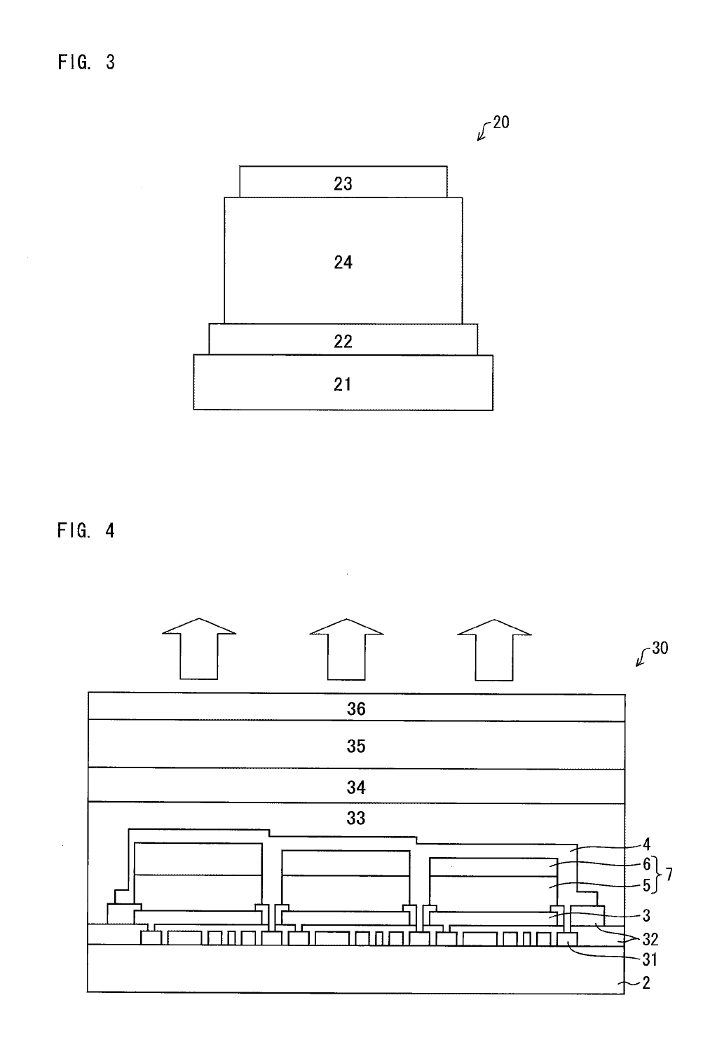

### DESCRIPTION OF EMBODIMENTS

An embodiment of an organic electroluminescent element of the present invention is described below with reference to FIG. 1. It should be noted that the term “organic electroluminescent element” is also hereinafter referred to simply as “organic EL element”.

[1. Configuration of an Organic EL Element]

FIG. 1 is a schematic view showing a configuration of an organic EL element according to an embodiment of the present invention.

As shown in FIG. 1, an organic EL element 1 according to the present embodiment includes an anode 3, a cathode 4, a hole transporting light-emitting layer 5, and an electron transporting light-emitting layer 6. The organic EL element 1 is a light-emitting element having a two-layer organic EL layer (organic light-emitting layer) 7. Specifically, the organic EL element 1 includes a two-layer organic EL layer 7 sandwiched between an anode 3 provided on a substrate 2 and a cathode 4 and composed of a hole transporting light-emitting layer 5 and an electron transporting light-emitting layer 6.

The anode 3 is an electrode which, when a voltage is applied to it, injects holes into the organic EL layer 7. The cathode 4 is an electrode which, when a voltage is applied to it, injects electrons into the organic EL layer 7. Although, in the present embodiment, the anode 3 is laminated directly on the substrate 2, the cathode 4 may be provided on the substrate 2 instead. That is, the anode 3 and the cathode 4 need only be placed so that the anode 3 functions as one of a pair of electrodes of the organic EL element 1 and the cathode 4 functions as the other one of the pair of electrodes.

The organic EL layer 7 is a light-emitting layer including a hole transporting light-emitting layer 5 located on an anode 3 and an electron transporting light-emitting layer 6 located on an anode 4.

The hole transporting light-emitting layer 5 is a light-emitting layer having hole transport capability. That is, the hole transporting light-emitting layer 5, which contains a hole transporting material, transports holes and emits light through the recombination of these charges. Further, that side of the hole transporting light-emitting layer 5 which faces the anode 3 is doped with an acceptor, and that side of the hole transporting light-emitting layer 5 which faces the cathode 4 is doped with a light-emitting dopant (first light-emitting dopant).

The electron transporting light-emitting layer 6 is a light-emitting layer having electron transport capability. That is, the electron transporting light-emitting layer 6, which contains an electron transporting material, transports electron and emits light through the recombination of these charges. Further, that side of the electron transporting light-emitting layer 6 which faces the cathode 4 is doped with a donor, and that side of the electron transporting light-emitting layer 6 which faces the anode 3 is doped with a light-emitting dopant (second light-emitting dopant).

The following describes each of the components of the organic EL element 1 in more detail.

(Configuration of the Organic EL Layer 7)

As mentioned above, the organic EL layer 7 is constituted by two layers, namely the hole transporting light-emitting layer 5 and the electron transporting light-emitting layer 6.

The hole transporting light-emitting layer 5 needs only contain the hole transporting material and be doped with the acceptor and the light-emitting dopant. However, the hole transporting light-emitting layer 5 is not to be limited to such a configuration. For example, the hole transporting light-emitting layer 5 may be obtained by dispersing the hole transporting material in a polymeric material such as a binder resin or in an inorganic material and doping the resulting product with the acceptor and the light-emitting dopant.

The electron transporting light-emitting layer 6 needs only contain the electron transporting material and be doped with the donor and the light-emitting dopant. However, the electron transporting light-emitting layer 6 is not to be limited to such a configuration. For example, the electron transporting light-emitting layer 6 may be obtained by dispersing the electron transporting material in a polymeric material such as a binder resin or in an inorganic material and doping the resulting product with the donor and the light-emitting dopant.

Further, that side of the hole transporting light-emitting layer 5 which faces the anode 3 is doped with the acceptor, and that side of the electron transporting light-emitting layer 6 which faces the cathode 4 is doped with the donor.

It should be noted here that an energy barrier has been formed at the interface between the organic EL layer 7 and each electrode and that the higher the energy barrier is, the more the injection of charges from the electrode is inhibited. In the organic EL element 1, there is a reduction in width of the energy barrier formed at the interface between the organic EL layer 7 and the electrode in an acceptor region (not illustrated) doped with the acceptor or in a donor region (not illustrated) doped with the donor. This brings about an improvement in the injection of charges by a tunneling effect through a narrow depletion region. This allows a sufficient increase in charge injection efficiency in that region and therefore makes it unnecessary to provide a hole injection layer or an electron injection layer between each electrode and the organic EL layer 7.

Furthermore, increasing the carrier concentration by acceptor or donor doping brings about a sufficient improvement in charge conductivity. This makes it unnecessary to provide a hole transport layer or an electron transport layer between each electrode and the organic EL layer 7. In this way, even when the organic EL element 1 is configured to omit hole and electron injection layers and hole and electron transport layers, the organic EL element 1 can achieve high-luminance and high-efficiency emission with a simple structure because the organic EL layer 5 functions both as a hole and electron injection layer and a hole and electron transport layer.

Further, when the organic EL layer 7 is formed, e.g., when the organic EL layer 7 is formed by using a cluster manufacturing method, each layer of the organic EL layer 7 is formed in a separate evaporation chamber. Therefore, in the organic EL element 1 according to the present embodiment, the organic EL layer 7 has a two-layer structure. This makes it only necessary to use two evaporation chambers. This makes it possible to reduce the number of evaporation chambers to be used, in comparison with a conventional multilayer organic EL element, thus making it possible to fabricate the organic EL element 1 at low cost.

The proportion of the acceptor region to the hole transporting light-emitting layer 5 in thickness can fall within any range. For example, assuming that the whole film thickness of the hole transporting light-emitting layer 5 accounts for 100%, it is only necessary that the proportion fall within a range of 90% or less from the anode 3 or, more preferably, 70% or less from the anode 3.

The proportion of the donor region to the electron transporting light-emitting layer 6 in thickness can fall within any range. For example, assuming that the whole film thickness of the electron transporting light-emitting layer 6 accounts for 100%, it is only necessary that the proportion fall within a range of 90% or less from the cathode 4 or, more preferably, 70% or less from the cathode 4.

Further, that side of the hole transporting light-emitting layer 5 which faces the cathode 4 and that side of the electron transporting light-emitting layer 6 which faces the anode 3 are doped with the light-emitting dopants, respectively. That is, an interfacial region of the hole transporting light-emitting layer 5 with the electron transporting light-emitting layer 6 and an interfacial region of the electron transporting light-emitting layer 6 with the hole transporting light-emitting layer 5 (first interfacial region, second interfacial region), both located in the center of the organic EL layer 7, are doped with the light-emitting dopants, respectively.

It should be noted that the interface between the hole transporting light-emitting layer 5 and the electron transporting light-emitting layer 6 has an effect of confining charges moving through the organic EL layer 7. Therefore, even if the mobility of holes and the mobility of electrons in the hole transporting light-emitting layer 5 and the electron transporting light-emitting layer 6 are different, it is possible to confine these charges in the light-emitting dopant regions. By thus letting holes and electrons stay at the interfacial regions between the hole transporting light-emitting layer 5 and the electron transporting light-emitting layer 6, the probability of holes and electrons being recombined with each other can be increased and the balance between charges can be maintained even under high luminance (under high electric current).

Furthermore, even in a case where there occurs a difference in decrease between hole mobility and electron mobility as caused by an aging process, the confinement of changes in the interfacial regions prevents breaking down of the balance between holes and electrons. This prevents a decrease in luminous efficiency and does not cause a color shift that is entailed by a movement of a site of recombination, thus making it possible to extend the life of the organic EL element 1. This makes it possible to keep high-luminance and high-efficiency emission over a long period of time.

The proportion of the light-emitting dopant region to the hole transporting light-emitting layer 5 in thickness can fall within any range. For example, assuming that the whole film thickness of the hole transporting light-emitting layer 5 accounts for 100%, it is only necessary that the proportion fall within a range of 50% or less from the side facing the cathode 4 or, more preferably, 20% or less from the side facing cathode 4. Further, it is preferable that the acceptor region be greater in film thickness than the light-emitting dopant region of the hole transporting light-emitting layer 5. This allows the hole transporting light-emitting layer 5 to effectively achieve both high hole transport capability and high luminous efficiency.

The proportion of the light-emitting dopant region to the electron transporting light-emitting layer 6 in thickness can fall within any range. For example, assuming that the whole film thickness of the electron transporting light-emitting layer 6 accounts for 100%, it is only necessary that the proportion fall within a range of 50% or less from the side facing the anode 3 or, more preferably, 20% or less from the side facing anode 3. Further, it is preferable that the donor region be greater in film thickness than the light-emitting dopant region of the electron transporting light-emitting layer 6. This allows the electron transporting light-emitting layer 6 to effectively achieve both high electron transport capability and high luminous efficiency.

Furthermore, it is preferable that a region containing neither the acceptor nor the light-emitting dopant be sandwiched between the acceptor region and the light-emitting dopant region in the hole transporting light-emitting layer 5. This prevents direct contact between the light-emitting dopant and the acceptor, thus preventing exciters produced in the light-emitting dopant from being deactivated by energy transfer to the acceptor. This makes it possible to more effectively achieve high luminous efficiency. Such a region containing neither the acceptor nor the light-emitting dopant is not particularly limited in thickness and, for example, only needs to have a thickness of 5 nm or greater or, more preferably, 10 nm or greater.

Further, it is preferable that a region containing neither the donor nor the light-emitting dopant be sandwiched between the donor region and the light-emitting dopant region in the electron transporting light-emitting layer 6. This prevents direct contact between the light-emitting dopant and the donor, thus preventing exciters produced in the light-emitting dopant from being deactivated by energy transfer to the donor. This makes it possible to more effectively achieve high luminous efficiency. Such a region containing neither the donor nor the light-emitting dopant is not particularly limited in thickness and, for example, only needs to have a thickness of 5 nm or greater or, more preferably, 10 nm or greater.

The film thickness of the organic EL layer 7 is not to be particularly limited and, for example, needs only fall within a range of 1 to 1,000 nm or, more preferably, 10 to 200 nm. For example, when the film thickness is 10 nm or greater, a pixel defect can be prevented from being caused by foreign bodies such as dirt. Further, for example, when the film thickness is 200 nm or less, a rise in drive voltage can be prevented from being caused by a resistance component of the organic EL layer 7.

It should be noted that in order for a microcavity effect (interference effect) to bring about an improvement in color purity, it is only necessary to adjust the film thickness optimally for each desired luminescent color.

(Materials Constituting the Organic El Layer 7)

Hole transporting materials are classified into low-molecular materials and polymeric materials. The hole transporting light-emitting layer 5 can be constituted by any hole transporting material. For example, the hole transporting light-emitting layer 5 can be constituted by a publicly known hole transporting material for use in organic EL.

Examples of low-molecular materials include: porphyrin compounds; aromatic tertiary amine compounds such as N,N′-bis(3-methylphenyl)-N,N′-bis (phenyl)-benzidine (TPD) and N,N′-di(naphthalene-1-yl)-N,N′-diphenyl-benzidine (NPD); hydrazone compounds; quinacridone compounds; styrylamine compounds; carbazole compounds such as 4,4-bis(carbazole)biphenyl and 9,9-di(4-dicarbazole-benzyl)fluorene (CPF); and the like.

Further, examples of polymeric materials include polyaniline (PANI), polyaniline-camphorsulfonic acid (PANI-CSA), 3,4-polyethylenedioxithiophene/polystyrenesulfonate (PEDOT/PSS), poly(triphenylamine) derivetives (Poly-TPD), poly(carbazole) derivatives (Poly-Cz), polyvinyl carbazole (PVCz), poly(p-phenylenevinylene) precursors (Pre-PPV), poly(p-naphthalenevinylene) precursors (Pre-PNV), etc.

Since, for high-efficiency emission, it is necessary to confine excitation energy into a phosphorescent light-emitting material, it is preferable that the hole transporting material have a singlet excitation level (S₁) that is higher in excitation level than the triplet excitation level (T₁) of the phosphorescent light-emitting material. Therefore, it is more preferable that the hole transporting material be a carbazole derivative, which is high in excitation level and hole mobility.

Electron transporting materials are classified into low-molecular materials and polymeric materials. The electron transporting light-emitting layer 6 can be constituted by any electron transporting material. For example, the electron transporting light-emitting layer 6 can be constituted by a publicly known electron transporting material for use in organic EL.

Examples of low-molecular materials include oxadiazole derivatives, triazole derivatives, thiopyrazine dioxide derivatives, benzoquinone derivatives, naphthoquinone derivatives, anthraquinone derivatives, diphenoquinone derivatives, fluorenone derivatives, benzofuran derivatives, etc.

Further, examples of polymeric materials include poly(oxadiazole) (Poly-OXZ), polystyrene derivatives (PSS), etc.

Since, for high-efficiency emission, it is necessary to confine excitation energy into a phosphorescent light-emitting material, it is preferable that the electron transporting material have a singlet excitation level (S₁) that is higher in excitation level than the triplet excitation level (T₁) of the phosphorescent light-emitting material. Therefore, it is more preferable that the electron transporting material be a triazole derivative or a benzofuran derivative, which is high in excitation level and hole mobility.

Further, it is possible to use any light-emitting dopant in the hole transporting light-emitting layer 5 and the electron transporting light-emitting layer 6. For example, it is possible to use a publicly known organic light-emitting material for use in organic EL.

Examples of such light-emitting dopants include: fluorescent materials such as styryl derivatives, perylene, iridium complexes, coumarin derivatives, Lumogen F Red, dicyanomethylnepyran, phenoxazone, and porphyrin derivatives; phosphorescent light-emitting organic metal complexes such as bis[(4,6-difluorophenyl)-pyridinato-N, C2′] picolinate iridium (III) (FIrpic), tris(2-phenylpyridyl) iridium (III) (Ir(ppy)₃), tris(1-phenylisoquinoline) iridium (III) (Ir(piq)₃), and tris(biphenylquinoxalinato) iridium (III) (Q3Ir); and the like.

For the purpose of drastically reducing power consumption, it is more preferable that the light-emitting dopants be phosphorescent light-emitting materials. It should be noted the light-emitting dopant contained in the hole transporting light-emitting layer 5 and the light-emitting dopant contained in the electron transporting light-emitting layer 6 may be identical to or different from each other. However, when these light-emitting dopants are identical materials, it is possible to form a common wide light-emitting dopant region for each layer in the interfacial regions between the hole transporting light-emitting layer 5 and the electron transporting light-emitting layer 6. This makes it possible to achieve high-efficiency emission by confining charges in the region.

Alternatively, the hole transporting light-emitting layer 5 or the electron transporting light-emitting layer 6 may have the aforementioned materials dispersed in another material specific examples of which include, but are not to be particularly limited to, polymeric materials such as polyvinyl carbazole, polycarbonate, polyethylene terephthalate and inorganic materials such as silicon oxide and tin oxide.

The acceptor is not to be particularly limited and may be made of a publicly known acceptor material for use in organic EL. Examples of acceptor materials include: inorganic materials such as gold (Au), platinum (Pt), tungsten (W), iridium (Ir), POCl₃, AsF₆, chloride (C1), barium (Br), iodine (I), vanadium oxide (V₂O₅), and molybdenum oxide (MoO₂); compounds having cyano groups, such as TCNQ (7,7,8,8,-tetracyanoquinodimethane), TCNQF₄ (tetrafluorotetracyanoquinodimethane), TCNE (tetracyanoethylene), HCNB (hexanecyanobutadiene), and DDQ (dicyclodicyanobenzoquinone); compounds having nitro groups, such as TNF (trinitrofluorenone) and DNF (dinitrofluorenone); and organic materials such as fluoranil, chloranil, and bromanil.

Among these acceptor materials, a compound having a cyano group, such as TCNQ, TCNQF4, TCNE, HCNB, DDQ, is more preferably used for a more effective increase in carrier concentration.

The donor is not to be particularly limited and may be made of a publicly known donor material for use in organic EL. Examples of donor materials include: inorganic materials such as alkali metals, alkali earth metals, rare earth elements, aluminum (Al), silver (Ag), copper (Cu), and indium (In); compounds each having an aromatic tertiary amine as its skeleton, such as anilines, phenylenediamines, benzidine (such as N,N,N′,N′-tetraphenylbenzidine,
N,N′-bis-(3-methylphenyl)-N,N′-bis-(phenyl)-benzidine, N,N′-di-(naphthalene-1-yl)-N,N′-diphenyl-benzidine), triphenylamines (such as triphenylamine,
4,4′,4″-tris(N,N-diphenyl-amino)-triphenylamine,
4,4′,4″-tris(N-3-methylphenyl-N-phenyl-amino)-triphenyl amine,
4,4′,4″-tris(N-(1-naphtyl)-N-phenyl-amino)-triphenylamin e), and triphenyldiamines (such as N,N′-di-(4-methyl-phenyl)-N,N′-diphenyl-1,4-phenylenedi amine); condensed polycyclic compounds such as phenanthrene, pyrene, perylene, anthracene, tetracene, and pentacene (Note, however, that such a condensed polycyclic compound may have a substituent); and organic materials such as TTFs (tetrathiafulvalenes), dibenzofuran, phenothiazine, and carbazole.

Among these donor materials, a compound having an aromatic tertiary amine as its skeleton, a condensed polycyclic compound, or an alkali metal is more preferably used for a more effective increase in carrier concentration.

It is preferable that the proportion of the acceptor material to be added to the hole transporting material be for example 0.1 to 50% by weight or, more preferably, 1 to 20% by weight. Further, it is preferable that the proportion of the donor material to be added to the electron transporting material be for example 0.1 to 50% by weight or, more preferably, 1 to 20% by weight. Furthermore, it is preferable that the proportions of the light-emitting dopants to be added to the hole transporting material and to the electron transporting material be for example 0.1 to 50% by weight or, more preferably, 1 to 20% by weight.

It is preferable that the content of the acceptor material in the hole transporting light-emitting layer 5 be higher than the content of the light-emitting dopant. This allows the hole transporting light-emitting layer 5 to more effectively achieve both high hole injection capability and high luminous efficiency.

It is preferable that the content of the donor material in the electron transporting light-emitting layer 6 be higher than the content of the light-emitting dopant. This allows the electron transporting light-emitting layer 6 to more effectively achieve both high electron injection capability and high luminous efficiency.

Further, it is preferable that the concentration of the light-emitting dopant contained in the hole transporting light-emitting layer 5 and the concentration of the light-emitting dopant contained in the electron transporting light-emitting layer 6 be different from each other. This makes it possible to compensate for a shift in charge transfer as caused by charge transfer in the light-emitting dopants and thereby keep the balance between charges. This makes it possible to achieve more high-efficiency emission.

It should be noted here that the organic EL element 1 is preferably configured such that the mobility of holes and the mobility of electrons in the hole transporting light-emitting layer 5 and the electron transporting light-emitting layer 6 satisfy relationships shown below.

That is, it is preferable that the mobility μh (HTM) of holes in the hole transporting material, the mobility μe (HTM) of electrons in the hole transporting material, the mobility μh (ETM) of holes in the electron transporting material, and the mobility μe (ETM) of electrons in the electron transporting material satisfy expressions (1) to (6) as follows:

0.1 μe(ETM)<μh(HTM)<10 μe(ETM) (1)

0.1 μh(HTM)<μe(ETM)<10 μh(HTM) (2)

μh(HTM)>100 μh(ETM) (3)

μe(ETM)>100 μe(HTM) (4)

μh(HTM)>100 μe(HTM) (5)

μe(ETM)>100 μh(ETM) (6)

For example, in a case where the organic EL element 1 satisfies expressions (1) and (2), the balance between holes moving through the hole transporting light-emitting layer 5 and electrons moving through the electron transporting light-emitting layer 6 can be optimized. This makes it possible to achieve high-efficiency emission by improving the rate of recombination of holes and electrons in the interfacial regions between the hole transporting light-emitting layer 5 and the electron transporting light-emitting layer 6.

It should be noted that in a case where the organic EL element 1 does not satisfy expressions (1) and (2), the charge mobility of the light-emitting dopants contribute to the charge transfer of the light-emitting layer (host material and the light-emitting dopants), so that the present invention loses its charge confining effect.

Alternatively, for example, in a case where the organic EL element 1 satisfies expressions (3) and (4), it is possible to more effectively confine charges in the interfacial regions by using a difference in hole mobility between the hole transporting light-emitting layer 5 and the electron transporting light-emitting layer 6 and a difference in electron mobility between the hole transporting light-emitting layer 5 and the electron transporting light-emitting layer 6. This makes it possible to achieve high-luminance emission by maintaining the balance between charges even under high luminance.

Alternatively, for example, in a case where the organic EL element 1 satisfies expressions (5) and (6), by making a difference between hole mobility and electron mobility in the hole transporting light-emitting layer 5 and a difference between hole mobility and electron mobility in the electron transporting light-emitting layer 5, breaking down of the balance between holes and electrons can be prevented even when there occurs a difference in decrease between hole mobility and electron mobility due to an aging process. This makes it possible to more effectively prevent a decrease in luminous efficiency and a color shift that is entailed by a movement of a site of recombination.

Examples of methods for forming an organic EL layer 7 include publicly known wet processes, publicly known dry processes, heat transfer, laser transfer, etc.

Examples of wet processes include: coating methods such as spin coating, dipping, a doctor blade method, spray coating; and printing methods such as ink jet printing, relief printing, intaglio printing, screen printing, microgravure coating, and nozzle printing.

In forming an organic EL layer 7 by using any of these wet processes, it is only necessary to use an organic-EL-layer-forming coating liquid obtained by dissolving and dispersing the aforementioned materials in a solvent such as a leveling agent. Further, it is possible to use additives to adjust the properties of the coating liquid. Examples of additives for improving the uniformity of the resulting coating film include acetone, chloroform, toluene, xylene, trimethyl benzene, tetramethyl benzene, chlorobenzene, dichlorobenzene, diethyl benzene, cymene, tetralin, cyclohexyl benzene, dodecyl benzene, isopropyl benzene, diisopropyl benzene, isopropy lxylene, t-butyl xylene, methylnaphthalene, etc. Further, examples of additives for adjusting viscosity include anisole, dimethoxybenzene, trimethoxybenzene, methoxytoluene, dimethoxytoluene, trimethoxytoluene, dimethyl anisole, trimethyl anisole, ethyl anosole, propyl anisole, isopropyl anisole, butyl anisole, methyl ethyl anisole, ethoxyether, butoxyether, benzyl methyl ether, benzyl ethyl ether, etc.

Further, examples of dry processes include vacuum evaporation, electron beam (EB) evaporation, molecular beam epitaxy (MBE), sputtering, organic vapor-phase deposition (OVPD), etc.

(Configuration of the Electrodes)

The electrodes constituting the organic EL element 1 need only function in pairs as the anode 3 and the cathode 4 do.

Each of the electrodes may be a single-layer structure made of a single electrode material or a laminated structure made of a plurality of electrode materials. Usable examples of electrode materials for the electrodes of the organic EL element 1 include, but are not to be particularly limited to, publicly known electrode materials.

A preferred example of an electrode material for the anode is an electrode material that can efficiently inject holes into the organic EL layer 7 and has a work function of 4.5 or greater, and a preferred example of an electrode material for the cathode is an electrode material that can efficiently inject electrons into the organic EL layer 7 and has a work function of 4.5 or less.

Examples of electrode materials having a work function of 4.5 or greater include: metals such as gold (Au), platinum (Pt), and nickel (Ni); and transparent electrode materials such as an oxide (ITO) composed of indium (In) and tin (Sn), an oxide (SnO₂) of tin (Sn), and an oxide (IZO) composed of indium (In) and zinc (Zn).

Examples of electrode materials having a work function of 4.5 or less include: metals such as lithium (Li), calcium (Ca), cerium (Ce), barium (Ba), and aluminum (Al); and alloys containing these metals such as a Mg:Ag alloy and a Li:Al alloy.

It should be noted that for efficient hole and electron injection, it is necessary that the anode of a conventional EL element be made of such an electrode material having a work function of 4.5 or greater and the cathode thereof be made of such an electrode material having a work function of 4.5 or less.

However, since, in the organic EL element 1 according to the present embodiment, the hole transporting light-emitting layer 5 of the organic EL layer 7 is doped with the acceptor and the electron transporting light-emitting layer 6 is doped with the donor, a change in band structure brings about an improvement in electron injection efficiency. Therefore, the anode 3 may be made of an electrode material having a work function of 4.5 or less, and the cathode 4 may be made of an electrode material having a work function of 4.5 or greater.

Examples of method for forming the electrodes include, but are not to be particularly limited to, publicly known methods such as EB evaporation, sputtering, ion plating, and resistance heating evaporation.

Further, it is also possible to pattern the resulting electrodes by photolithography or laser ablation as needed. Furthermore, it is also possible to from directly patterned electrodes by combining any of the above public known methods with a shadow mask.

It is preferable that each of the electrodes have, but be not to be particularly limited to, a film thickness of 50 nm or greater. For example, when each of the electrodes has a film thickness of 50 nm or greater, a rise in drive voltage due to an increase in wiring resistance can be prevented.

It should be noted that emitted light obtained in the organic EL layer 7 may be taken out through one of the electrodes, i.e., may be radiated outward. In this case, it is preferable to use a transparent electrode as the electrode through which the emitted light is taken out. Especially preferred examples of transparent electrode materials for the transparent electrode include, but are not to be particularly limited to, ITO and IZO.

It is preferable that the transparent electrode have a film thickness ranging for example from 50 to 500 nm or, more preferably, from 100 to 300 nm. For example, when the transparent electrode has a film thickness of 50 nm or greater, a rise in drive voltage due to an increase in wiring resistance can be prevented. Further, when the transparent electrode has a film thickness of 500 nm or less, a decrease in luminance can be prevented without a decrease in light transmission.

In order for a microcavity effect (interference effect) to bring about an improvement in color purity or in luminous efficiency, it is preferable to use a translucent electrode as the electrode through which the emitted light is taken out. Usable examples of electrode materials for the translucent electrode include a single metal translucent electrode material and a combination of a metal translucent electrode material and a transparent electrode material. From a point of view of reflectivity and transmissivity, it is preferable to use silver as such a translucent electrode material.

It is preferable that the translucent electrode have a film thickness ranging for example from 5 to 30 nm. For example, when the translucent electrode has a film thickness of 5 nm or greater, light can be sufficiently reflected, so that a sufficient interference effect can be obtained. Further, when the translucent electrode has a film thickness of 30 nm or less, there is no rapid decrease in light transmission, so that a decrease in luminance and luminous efficiency can be prevented.

Further, in a case where the emitted light obtained the organic EL layer 7 is taken out through the anode 3 (or the cathode 4), it is preferable that the cathode 4 (or the anode 3), which is the other electrode, be made of an electrode material that does not transmit light. Usable examples of such electrode materials include: black electrode materials such as tantalum and carbon; reflecting metal electrode materials such as aluminum, silver, gold, an aluminum-lithium alloy, an aluminum-neodymium alloy, and an aluminum-silicon alloy; and a combination of a transparent electrode material and such a reflecting metal electrode (reflecting electrode) material.

[2. Organic EL Display Device]

Next, an embodiment of an organic EL display device according to the present invention is described below with reference to FIG. 4. FIG. 4 is a schematic view showing a configuration of an organic EL panel (display means) according to an embodiment of the present invention.

The organic EL display device according to the present embodiment is an active-matrix display device including such an organic EL element 1 as that described above. Specifically, the organic EL display device according to the present embodiment includes an organic EL panel 30 constituted by a plurality of organic EL elements 1 laminated on an active-matrix substrate on which TFTs (thin-film transistors) have been formed.

(Configuration of the Organic EL Panel 30)

As shown in FIG. 4, the organic EL panel 30 according to the present embodiment includes a substrate 2, anodes 3, cathodes 4, organic EL layers 7, TFT circuits/wires 31, an interlayer insulating film 32, a sealing film 33, a resin film 34, a sealing substrate 35, and a polarizer 36.

The substrate 2, on an upper surface of which the TFT circuits/wires 31 are provided, functions as an active-matrix substrate. The active-matrix substrate includes: a plurality of scanning signal lines disposed on the substrate 2, which serves as a base material; a plurality of data signal lines disposed on the substrate 2; and TFTs disposed at intersections between the scanning signal lines and the data signal lines. Further, with a pair of two rows of active-matrix drive elements thus configured, the scanning signal lines are disposed above and below each other.

The active-matrix substrate has a switching TFT and a driving TFT for each pixel, and an interlayer insulating film 32 and a planarizing layer (not illustrated) are formed in this order over the TFTs. Among these TFTs, the driving TFT is electrically connected to an anode 3 via a contact hole formed in the planarizing layer. Further provided in each single pixel is a retention capacitor connected to a gate part of the driving TFT. This retention capacitor retains the gate potential of the driving TFT at a constant potential.

Further, the organic EL layers 7 need only be juxtaposed or laminated on the plurality of anode 3 placed on the active-matrix substrate. It should be noted here that preferred examples of organic EL layers 7 for use in an organic EL panel are, but are not to be particularly limited to, red, green, and blue organic EL layers 7. This makes it possible to achieve a full-color organic EL display device. Each of these organic EL layers 7 functions as an organic EL element 1 by having a cathode 4 provided on that organic EL layer 7.

It should be noted that the organic EL panel 30 according to the present embodiment is driven by a voltage-driven digital gradation method. However, this does not imply any limitation. For example, the organic EL panel 30 according to the present embodiment may be driven by a current-driven analog gradation method.

The number of TFTs is not to be particularly limited, and it is possible to use two TFTs to drive each organic EL element 1 or use two or more TFTs to drive each organic EL element 1. Use of two or more TFTs prevents variation among the TFTs.

Further, in order to protect uppermost surfaces of the organic EL elements 1, i.e., surfaces of the cathodes that are not in contact with the active-matrix substrate, it is possible to provide either the sealing film 33 on the cathodes 4 or the sealing substrate 35 via the resin film 34. This makes it possible to protect the organic EL elements 1 from moisture and the like.

Furthermore, the organic EL panel 30 may include the polarizer 36 on the sealing substrate 35. This makes it possible to improve the contrast of the organic EL panel 30.

Next, the components of the organic EL panel 30 according to the present embodiment are described in detail.

(Substrate 2)

Examples of the substrate 2 include: an inorganic material substrate containing glass, quartz, or the like; a plastic substrate containing polyethylene terephthalate, polycarbazole, or polyimide; an insulating substrate such as a ceramic substrate containing alumina or the like; a substrate obtained by coating a surface of a metal substrate containing aluminum (Al), iron (Fe), or the like with an insulator containing silicon oxide (SiO₂), an organic insulating material, or the like; a substrate obtained by subjecting a surface of a metal substrate containing Al or the like to insulating treatment by a method such as anodization; and the like.

It should be noted here that in a case where a polysilicon TFT is formed by a low-temperature process for active-matrix driving of each organic EL element 1, it is more preferable that the substrate 2 be a substrate that neither melts nor distorts at a temperature of 500° C. or lower. Furthermore, in a case where such a polysilicon TFT is formed by a high-temperature process, it is more preferable that the substrate 2 be a substrate that neither melts nor distorts at a temperature of 1,000° C. or lower.

Further, in a case where emitted light obtained in the organic EL panel 30, e.g., in each organic EL layer 7 is taken out through a side of the organic EL element 1 that is not contact with the active-matrix substrate, i.e., through the cathode 4 (in the direction of arrows above the polarizer 36 in FIG. 4), the substrate 2 is made of any material; however, in a case where the emitted light is taken out through the electrode that is in contact with the active-matrix substrate, i.e., through the anode 3, it is preferable that the substrate 2 be made of a transparent or translucent substrate material.

(TFT Circuits/Wires 31)

It is only necessary to use publicly known TFTs as the TFTs, and it is possible to use metal-insulator-metal (MIM) diodes instead of the TFTs.

Further, the TFTs can be formed by using a publicly known material, structure, and forming method. Examples of materials for the active layer of each TFT include: inorganic semiconductor materials such as amorphous silicon, polycrystalline silicon (polysilicon), microcrystalline silicon, and cadmium selenide; and organic semiconductor materials such as polythiophene derivatives, thiophene oligomers, poly(p-phenylenevinylene) derivatives, naphthacene, and pentacene. Further, examples of the structure of each TFT include a staggered structure, an inverted-staggered structure, a top-gate structure, and a coplanar structure.

Examples of methods for forming an active layer that constitutes a TFT include: a method for ion-doping an impurity into an amorphous silicon film formed by plasma-excited chemical vapor deposition (PECVD); a method for forming amorphous silicon by low-pressure chemical vapor deposition (LPCVD) using a silane (SiH₄) gas, for crystallizing the amorphous silicon by solid-phase deposition to form polysilicon, and for doping ions into the polysilicon by ion implantation; a method (low-temperature process) for forming amorphous silicon by LPCVD using a Si₂H₆ gas or by PECVD using SiH₄ gas, for annealing the amorphous silicon with a laser such as an excimer laser, for crystallizing the amorphous silicon to form polysilicon, and for doping ions into the polysilicon; a method (high-temperature process) for forming a polysilicon layer by LPCVD or PECVD, for forming a gate insulating film by thermally oxidizing the polysilicon layer at 1,000° C. or higher, for forming an n+ polysilicon gate electrode on the polysilicon layer, and for doping ions; a method for forming an organic semiconductor material by ink jet printing; a method for obtaining a single-crystal film of an organic semiconductor material; and the like.

The gate insulating film of each TFT can be formed by using a publicly known material, examples of which include: SiO₂ formed by PECVD, LPCVD, or the like; SiO₂ obtained by thermally oxidizing polysilicon; and the like. Further, a signal electrode wire, a scanning electrode wire, a common electrode wire, a first drive electrode, and a second drive electrode for use in each TFT of the organic EL panel 30 according to the present embodiment can be formed by using a publicly known material, examples of which include tantalum (Ta), aluminum (Al), copper (Cu), and the like. The TFTs of the organic EL panel according to the present embodiment can be formed to have such a configuration as that described above, but are not to be limited to these materials, structures, and forming methods.

(Interlayer Insulating Film 32)

The interlayer insulating film 32 needs only be made of a publicly known material, examples of which include: inorganic materials such as silicon oxide (SiO₂), silicon nitride (SiN or Si₂N₄), and tantalum oxide (TaO or Ta₂O₅); organic materials such as acrylic resin and resist materials; and the like.

Examples of methods for forming the interlayer insulating film 32 include publicly dry processes such as chemical vapor deposition (CVD) and vacuum evaporation and wet processes such as spin coating. Further, it is possible to carry out patterning by photolithography or the like as needed.

Further, in a case where emitted light obtained in each organic EL layer 7 is taken out through a side of the organic EL element 1 that is not contact with the active-matrix substrate, i.e., through the cathode 4, it is preferable that the interlayer insulating film 52 be a light-blocking insulating film having a light-blocking effect. Thus, even if outside light enters a TFT formed on the substrate, a change in TFT characteristic can be prevented.

Examples of light-blocking interlayer insulating films include: one obtained by dispersing a pigment or dye such as phthalocyanine or quinacridone in polymer resin such as polyimide; color resists; black matrix materials, inorganic insulating materials such as NixZnyFe₂O₄; and the like. It should be noted that the interlayer insulating film may be any of these insulating films or light-blocking insulating films or a combination of them. The interlayer insulating film of the organic EL panel according to the present embodiment can be formed to have such a configuration as that described above, but is not to be limited to these materials, structures, and forming methods.

(Planarizing Film)

The formation of the TFTs and the like on the substrate 2 causes the surface of the substrate to be uneven. In order to prevent the occurrence of a defect in an organic EL element 1 due to such unevenness (e.g., a defect in a pixel electrode, a defect in an organic EL layer, a breakage in a counter electrode, a short circuit between a pixel electrode and a counter electrode, a decrease in resistance to pressure, etc.), a planarizing film may be provided on the interlayer insulating film 32.

The planarizing film can be made of a publicly known material, examples of which include: inorganic materials such as silicon oxide, silicon nitride, and tantalum oxide; organic materials such as polyimide, acrylic resin, resist materials; and the like.

Examples of methods for forming the planarizing film include dry processes such as CVD and vacuum evaporation and wet processes such as spin coating. However, the present invention is not to be limited to these materials and forming methods. Further, the planarizing film may have a single-layer structure or a multilayer structure.

(Organic El Element 1)

Each of the organic EL elements 1 of the organic EL panel 30 according to the present embodiment needs only include an organic EL layer 7 composed of two layers. However, none of the organic EL elements 1 is to be limited to the aforementioned configuration. For example, an insulating edge cover for preventing a leak may be provided in that edge portion of an electrode which is in contact with a surface of active-matrix substrate. In a case where the organic EL elements 1 are fabricated by a wet process, an insulating separating wall for retaining a coating liquid to be applied may be provided.

(Polarizer 36)

Further, the organic EL panel 30 of the present invention may have the polarizer 36 provided on a side through which emitted light obtained in the organic EL layers 7 is taken out. A more preferred example of the polarizer 36 is, but is not to be limited to, a combination of a conventional linear polarizer and a quarter wavelength plate. The provision of the polarizer 36 brings about an improvement in contrast of the organic EL panel 30.

(Sealing Film 33, Sealing Substrate 35)

It is preferable that the organic EL panel 30 according to the present embodiment have a sealing structure including the sealing film 33 or the sealing substrate 35. The sealing structure may for example be configured by a combination of the sealing film 33 and the sealing substrate 35 or configured by using only either the sealing film 33 or the sealing substrate 35.

The sealing film 33 is for example an inorganic film, a resin film, or the like, and the sealing substrate 35 is for example a glass substrate or the like. It should be noted that in case where emitted light obtained in the organic EL layers 7 is taken out through a side on which a sealing structure has been formed, it is preferable that the sealing film 33 or the sealing substrate 35 be made of a transparent material.

Examples of methods for forming the sealing film 33 and the sealing substrate 35 include, but are not to be particularly limited to, publicly known methods with use of publicly known materials, examples of which include: a method for sealing in an inert gas such as a nitrogen gas or an argon gas with glass, metal, or the like; a method of mixing an absorbent or the like such as barium oxide into an inert gas that has been sealed in; and the like. Another example of a method for forming the sealing film 33 is to apply or join resin onto the electrodes by spin coating, ODF (one drop fill), or lamination.

The provision of the sealing structure on the electrodes makes it possible to prevent external oxygen or moisture from entering the organic EL elements 1, thereby extending the life of the organic EL elements 1. It should be noted that neither the materials for nor the method for forming the sealing film 33 or the sealing substrate 35 is to be so limited.

It should be noted that the present invention is not to be limited to the organic EL display device described above, and an organic EL lighting device including an organic EL element according to the present invention is also encompassed in the scope of the present invention.

### EXAMPLES

In the following, the present invention is described on the basis of examples. It should be noted, however, that the present invention is not limited to these examples.

### Example 1

### Evaluation of the Electrical Characteristics of an Organic Electroluminescent Element according to the Present Invention

In Example 1, an organic EL element was fabricated in the following manner, and its electrical characteristics and charge mobility were evaluated.

(Fabrication of an Organic EL Element)

First, a transparent substrate on a surface of which a 50 mm×50 mm indium tin oxide (ITO) having a surface resistance of 10Ω/□ had been formed was used. The ITO, which would serve as an anode, was patterned into a stripe 2 mm in width. Next, the substrate was subjected to water washing, was further subjected to ten minutes of pure water ultrasonic washing, ten minutes of acetone ultrasonic washing, and five minutes of isopropyl alcohol steam washing, and was dried for one hour at 100° C. After that, the substrate was fixed to a substrate holder provided inside of a resistance heating evaporation apparatus, and the pressure was reduced to a vacuum of 1×10⁻⁴ Pa or lower.

Next, on the substrate, a hole transporting light-emitting layer 60 nm in film thickness was formed. It should be noted here that the hole transporting material used was diphenylamino benzodifuran (DPABDF), that the acceptor used was tetrafluorotetracyanoquinodimethane (TCNQF₄), and that the light-emitting dopant used was tris(2-phenylpyridine) iridium (III) (Ir(ppy)₃).

It should be noted that a region in the hole transporting light-emitting layer which extended from the anode to a position at a distance of 40 nm from the anode was doped with TCNQF₄ by co-evaporation so that TCNQF₄ had a doping concentration of 15% by weight, and that a region in the hole transporting light-emitting layer which extended from the electron transporting light-emitting layer to a position at a distance of 20 nm from the electron transporting light-emitting layer was doped with Ir(ppy)₃ by co-evaporation so that Ir(ppy)₃ had a doping concentration of 8% by weight.

Next, the electron transporting light-emitting layer, 60 nm in film thickness, was formed by using triterpyridyl benzene (TbpyB) as the electron transporting material, tetrathiafulvalene (TTF) as the donor, and Ir(ppy)₃ as the light-emitting dopant.

It should be noted that a region in the electron transporting light-emitting layer which extended from the cathode to a position at a distance of 40 nm from the cathode was doped with TTF by co-evaporation so that TTF had a doping concentration of 10% by weight, and that a region in the electron transporting light-emitting layer which extended from the hole transporting light-emitting layer to a position at a distance of 20 nm from the hole transporting light-emitting layer was doped with Ir(ppy)₃ by co-evaporation so that Ir(ppy)₃ had a doping concentration of 6% by weight.

Next, the cathode, 100 nm in film thickness, was formed by depositing silver (Ag) on the hole transporting light-emitting layer (at a deposition rate of 2 nm/sec).

Finally, the resulting substrate was joined to a glass substrate with a UV (ultraviolet) curing resin sandwiched therebetween, and the resin was cured for sealing by irradiating it with UV light of 6,000 nm from a UV lamp. Thus obtained was an organic EL element composed of the anode, an organic light-emitting layer composed of two layers (namely the hole transporting light-emitting layer and the electron transporting light-emitting layer), and the cathode.

(Evaluation of the Electrical Characteristics and Charge Mobility of the Organic EL Element)

Next, the electrical characteristics and charge mobility of the organic EL element obtained in Example 1 were evaluated. It should be noted that the electrical characteristics were measured by using an OLED device optical characteristic inspecting apparatus (manufactured by Otsuka Electronics Co., Ltd.). Further, the mobility of charges in each material was measured by using a photoexcited carrier mobility measuring apparatus (TOF-401) (manufactured by Sumitomo Heavy Industries, Ltd.).

As a result, the mobility of holes in the hole transporting material was 1.8×10⁻³ cm²/Vs (at a field intensity of 0.5 MV/cm), and the mobility of electrons in the hole transporting material was 2.4×10⁻⁸ cm²/Vs (at a field intensity of 0.5 MV/cm). Further, the mobility of holes in the electron transporting material was 2.6×10⁻⁷ cm²/Vs (at a field intensity of 0.5 MV/cm), and the mobility of electrons in the electron transporting material was 3.7×10⁻⁴ cm²/Vs (at a field intensity of 0.5 MV/cm).

### Example 2

In Example 2, an electron transporting light-emitting layer 60 nm in film thickness was formed by using pyridyl-triazole (PyTAZ) as the electron transporting material, cesium (Cs) as the donor, and Ir(ppy)₃ as the light-emitting dopant. However, a region in the electron transporting light-emitting layer which extended from the cathode to a position at a distance of nm from the cathode was doped with Cs by co-evaporation so that Cs had a doping concentration of 8% by weight, and a region in the electron transporting light-emitting layer which extended from the hole transporting light-emitting layer to a position at a distance of 20 nm from the hole transporting light-emitting layer was doped with Ir(ppy)₃ by co-evaporation so that Ir(ppy)₃ had a doping concentration of 8% by weight. Except for this, an organic EL element was fabricated in the same manner as in Example 1.

As a result of the measurement of the mobility of charges in each material of the organic EL element of Example 2 in the same manner as in Example 1, the mobility of holes in the electron transporting material was 1.0×10⁻⁵ cm²/Vs (at a field intensity of 0.5 MV/cm), and the mobility of electrons in the electron transporting material was 9.2×10⁻⁴ cm²/Vs (at a field intensity of 0.5 MV/cm).

### Example 3

In Example 3, a hole transporting light-emitting layer 60 nm in film thickness was formed by using bis(carbazolin)benzodifuran (CZBDF) as the hole transporting material, TCNQF₄ as the acceptor, and Ir(ppy)₃ as the light-emitting dopant. However, a region in the hole transporting light-emitting layer which extended from the anode to a position at a distance of 40 nm from the anode was doped with TCNQF₄ by co-evaporation so that TCNQF₄ had a doping concentration of 10% by weight, and a region in the hole transporting light-emitting layer which extended from the electron transporting light-emitting layer to a position at a distance of 20 nm from the electron transporting light-emitting layer was doped with Ir(ppy)₃ by co-evaporation so that Ir(ppy)₃ had a doping concentration of 13% by weight.

The electron transporting light-emitting layer, 60 nm in film thickness, was formed by using CZBDF as the electron transporting material, TTF as the donor, and Ir(ppy)₃ as the light-emitting dopant. However, a region in the electron transporting light-emitting layer which extended from the cathode to a position at a distance of nm from the cathode was doped with Cs by co-evaporation so that Cs had a doping concentration of 20% by weight, and a region in the electron transporting light-emitting layer which extended from the hole transporting light-emitting layer to a position at a distance of 20 nm from the hole transporting light-emitting layer was doped with Ir(ppy)₃ by co-evaporation so that Ir(ppy)₃ had a doping concentration of 20% by weight. Except for this, an organic EL element was fabricated in the same manner as in Example 1.

As a result of the measurement of the mobility of charges in each material of the organic EL element of Example 3 in the same manner as in Example 1, the mobility of holes in the electron transporting material was 3.8×10⁻³ cm²/Vs (at a field intensity of 0.5 MV/cm), and the mobility of electrons in the electron transporting material was 4.6×10⁻⁴ cm²/Vs (at a field intensity of 0.5 MV/cm).

### Example 4

In Example 4, an electron transporting light-emitting layer 60 nm in film thickness was formed by using 2,9-dimethyl-4,7-diphenyl-1,10-phenanthroline (BCP) as the electron transporting material, Cs as the donor, and Ir(ppy)₃ as the light-emitting dopant. However, a region in the electron transporting light-emitting layer which extended from the cathode to a position at a distance of 40 nm from the cathode was doped with Cs by co-evaporation so that Cs had a doping concentration of 8% by weight, and a region in the electron transporting light-emitting layer which extended from the hole transporting light-emitting layer to a position at a distance of 20 nm from the hole transporting light-emitting layer was doped with Ir(ppy)₃ by co-evaporation so that Ir(ppy)₃ had a doping concentration of 8% by weight. Except for this, an organic EL element was fabricated in the same manner as in Example 1.

As a result of the measurement of the mobility of charges in each material of the organic EL element of Example 4 in the same manner as in Example 1, the mobility of holes in the electron transporting material was 2.4×10⁻⁹ cm²/Vs (at a field intensity of 0.5 MV/cm), and the mobility of electrons in the electron transporting material was 6.2×10⁻⁷ cm²/Vs (at a field intensity of 0.5 MV/cm).

### Example 5

In Example 5, by using the same materials as in Example 1, a hole transporting light-emitting layer 60 nm in film thickness was formed to include (i) a region, nm in film thickness, doped with TCNQF₄, (ii) a region, 15 nm in film thickness, doped with Ir(ppy)₃, and (iii) a region, 15 nm in film thickness, doped with nothing and provided between the region doped with TCNQF₄ and the region doped with Ir(ppy)₃. Further, an electron transporting light-emitting layer was formed to include (i) a region, 30 nm in film thickness, doped with TTF, (ii) a region, 15 nm in film thickness, doped with Ir(ppy)₃, and (iii) a region, 15 nm in film thickness, doped with nothing and provided between the region doped with TTF and the region doped with Ir(ppy)₃. Except for this, an organic EL element was fabricated in the same manner as in Example 1.

The organic EL element of Example 5 was measured in the same manner as in Example 1.

### Comparative Example 1

### Multilayer Organic Electroluminescent Element

In Comparative Example 1, an organic EL element composed of six organic layers was fabricated in the following manner.

First, a transparent substrate on a surface of which a 50 mm×50 mm indium tin oxide (ITO) having a surface resistance of 10Ω/□ had been formed was used. The ITO, which would serve as an anode, was patterned into a stripe 2 mm in width. Next, the substrate was subjected to water washing, was further subjected to ten minutes of pure water ultrasonic washing, ten minutes of acetone ultrasonic washing, and five minutes of isopropyl alcohol steam washing, and was dried for one hour at 100° C. After that, the substrate was fixed to a substrate holder provided inside of a resistance heating evaporation apparatus, and the pressure was reduced to a vacuum of 1×10⁻⁴ Pa or lower.

Next, with use of LGC101 (manufactured by LG Chem, LTD.) as a hole injection material, a hole injection layer 20 nm in film thickness was formed by resistance heating evaporation.

After that, with use of N,N′-di-1-naphthyl-N,N′-diphenyl-1,1′biphenyl-1,1′-biphe nyl-4,4′-diamine (NPB) as a hole transporting material, a hole injection layer 40 nm in film thickness was formed by resistance heating evaporation.

Further, with use of 4,4′-bis(carbazole-9-yl)biphenyl (CBP) as a host material and tris(2-phenylpyridine) iridium (III) (Ir(ppy)₃) as a light-emitting dopant, a light-emitting layer 30 nm in film thickness was formed by resistance heating evaporation. In so doing, the host material was doped with 8% by weight of Ir(ppy)₃ by co-evaporation.

Next, with use of 2,9-dimethyl-4,7-diphenyl-1,10-phenanthroline (BCP) as a hole blocking material, a hole blocking layer 10 nm in film thickness was formed by resistance heating evaporation.

After that, with use of an aluminum quinolyl complex (Alq3) as an electron transporting material, an electron transport layer 20 nm in film thickness was formed by resistance heating evaporation.

Further, with use of lithium fluoride (LiF) as an electron injection material, an electron injection layer 1 nm in film thickness was formed by resistance heating evaporation.

Furthermore, a cathode 100 nm in film thickness was formed by depositing silver (Ag) on the electron injection layer (at a deposition rate of 2 nm/sec).

Finally, the resulting substrate was joined to a glass substrate with a UV (ultraviolet) curing resin sandwiched therebetween, and the resin was cured for sealing by irradiating it with UV light of 6,000 mJ from a UV lamp. Thus obtained was an organic EL element composed of the anode, the hole injection layer, the hole transport layer, the light-emitting layer, the hole blocking layer, the electron transport layer, the electron injection layer, and the cathode, i.e., constituted by a multilayer organic layer.

The electrical characteristics of the organic EL element of Comparative Example 1 and the mobility of charges in each material thereof were measured in the same manners as in Example 1.

The following is a table of results obtained in Examples 1 to 5 and Comparative Example 1.

TABLE 1

| | Hole transporting material | | | | Electron transporting material | | | | | | | | | | | |
|---|---|---|---|---|---|---|---|---|---|---|---|---|---|---|---|---|
| | | Hole | Electron | | | Hole | Electron | | Relational | | | | | | Luminous | |
| | | mobility | mobility | T1 | | mobility | mobility | T1 | Expressions | | | | | | efficiency | Luminance |
| | Material | (cm²/Vs) | (cm²/Vs) | (eV) | Material | (cm²/Vs) | (cm³/Vs) | (eV) | 1 | 2 | 3 | 4 | 5 | 6 | (cd/A) | (cd/m²) |
| Comp. | — | — | — | — | — | — | — | — | | | | | | | 35 | 10,000 |
| Ex. 1 | | | | | | | | | | | | | | | | |
| Example 1 | DPABDF | 1.8 × 10⁻³ | 2.4 × 10⁻³ | 8.0 | TbpyB | 2.6 × 10⁻⁷ | 8.7 × 10⁻⁴ | 2.9 | ∘ | ∘ | ∘ | ∘ | ∘ | ∘ | 40 | 15,000 |
| Example 2 | DPABDF | 1.8 × 10⁻³ | 2.4 × 10⁻³ | 3.0 | PyTAZ | 1.0 × 10⁻⁵ | 9.2 × 10⁻⁴ | 2.9 | ∘ | ∘ | ∘ | ∘ | ∘ | x | 21 | 5,000 |
| Example 3 | CZBDF | 3.8 × 10⁻³ | 4.6 × 10⁻³ | 3.1 | CZBDF | 3.8 × 10⁻³ | 4.6 × 10⁻³ | 3.1 | ∘ | ∘ | x | x | x | x | 18 | 3,500 |
| Example 4 | DPABDF | 1.8 × 10⁻³ | 2.4 × 10⁻³ | 3.0 | BCP | 2.4 × 10⁻⁹ | 6.2 × 10⁻⁷ | 2.9 | x | x | ∘ | x | ∘ | ∘ | 15 | 1,500 |
| Example 5 | DPABDF | 1.8 × 10⁻³ | 2.4 × 10⁻³ | 3.0 | TbpyB | 2.6 × 10⁻⁷ | 3.7 × 10⁻⁴ | 2.9 | ∘ | ∘ | ∘ | ∘ | ∘ | ∘ | 45 | 25,000 |

It should be noted that in this table, the mobility indicates a value obtained at a field intensity of 0.5 MV/cm. Further, those organic EL elements which satisfied any of the relational expressions (1) to (6) shown in the embodiment were marked with “∘”, and those which did not were marked with “×”.

These results show that the organic EL element of Example 1, which satisfied all of the relational expressions (1) to (6), is higher in luminous efficiency and luminance than the organic EL element of Comparative Example 1.

### Example 6

### Fabrication of an Organic EL Display Device

In this example, an organic EL display device was fabricated in the following manner.

First, an amorphous silicon semiconductor film was formed by PECVD on a glass substrate. By subjecting the resulting substrate to crystallization, a polysilicon semiconductor film was formed.

Next, the polysilicon semiconductor film was patterned by photolithography into a plurality of islands. Then, on the polysilicon semiconductor film thus patterned, a gate insulating film and a gate electrode layer were formed in this order and patterned by photolithography.

After that, source and drain regions were formed by doping an impurity element such as phosphorous into the polysilicon semiconductor film thus patterned, and a planarizing film was formed after TFT elements had been fabricated.

The planarizing film was formed by first forming a silicon nitride film by PECVD and then laminating an acrylic resin layer by spin coating.

Specifically, by first forming the silicon nitride film and then etching the silicon nitride film and the gate insulating film altogether, contact holes that lead up to the source and/or drain regions were formed, and then source wires were formed. After that, the acrylic resin layer was formed, and contact holes that lead up to the drain regions were formed in the same positions as the drain region contact holes made in the gate insulating film and in the silicon nitride film. Thus, an active-matrix substrate was obtained.

It should be noted the planarizing film has its function realized by the acrylic resin layer. Further, a retention capacitor for retaining the gate potential of each TFT at a constant potential was formed by sandwiching an insulating film such as an interlayer insulating film between the drain of each switching TFT and the source of each driving TFT.

On the active-matrix substrate, contact holes were provided which passed through the planarizing layer and which electrically connected driving TFTs to the first electrodes (anodes or cathodes) of red, green, and blue organic EL elements.

Each of the first electrodes was formed by forming a 100 nm film of Ag (silver) and then forming a 20 nm film of ITO (indium oxide-tin oxide). At this point in time, each of the first electrodes had an area of 300 μm×300 μm.

Next, a 200 nm layer of SiO₂ was laminated on the first electrode by sputtering and patterned by conventional photolithography so as to cover an edge portion of the first electrode. An active substrate was obtained which had such a structure that the four sides of each first electrode were covered with SiO₂ by 10 μm from the edge.

The resulting active substrate was washed. Specifically, the resulting active-matrix substrate was subjected to ten minutes of ultrasonic washing with acetone and IPA and then thirty minutes of UV-ozone washing.

(Formation of a Blue Pixel)

Next, a blue light-emitting pixel was formed on a surface of a first electrode by an evaporation method using a shadow mask. With use of DPABDF as the hole transporting material, TCNQF₄ as the acceptor, and bis[(4,6-difluorophenyl)-pyridinato-N, C2] (picolinato) iridium (III) T1=2.8 eV (Flrpic) as a blue light-emitting dopant, a hole transporting light-emitting layer 60 nm in film thickness was formed.

However, a region in the hole transporting light-emitting layer which extended from the anode to a position at a distance of 40 nm from the anode was doped with TCNQF₄ by co-evaporation so that TCNQF₄ had a doping concentration of 15% by weight, and a region in the hole transporting light-emitting layer which extended from the electron transporting light-emitting layer to a position at a distance of 20 nm from the electron transporting light-emitting layer was doped with Flrpic by co-evaporation so that Flrpic had a doping concentration of 5% weight.

Next, the electron transporting light-emitting layer, 60 nm in film thickness, was formed by using TbpyB as the electron transporting material, TTF as the donor, and Flrpic as the blue light-emitting dopant.

However, a region in the electron transporting light-emitting layer which extended from the cathode to a position at a distance of 40 nm from the cathode was doped with TTF by co-evaporation so that TTF had a doping concentration of 10% by weight, and a region in the electron transporting light-emitting layer which extended from the hole transporting light-emitting layer to a position at a distance of 20 nm from the hole transporting light-emitting layer was doped with Flrpic by co-evaporation so that Flrpic had a doping concentration of 10% by weight.

(Formation of a Green Pixel)

Next, a green light-emitting pixel was formed on a surface of a first electrode by an evaporation method using a shadow mask. With use of DPABDF as the hole transporting material, TCNQF₄ as the acceptor, and Ir(ppy)₃ as a green light-emitting dopant, a hole transporting light-emitting layer 160 nm in film thickness was formed.

However, a region in the hole transporting light-emitting layer which extended from the anode to a position at a distance of 40 nm from the anode was doped with TCNQF₄ by co-evaporation so that TCNQF₄ had a doping concentration of 15% by weight, and a region in the hole transporting light-emitting layer which extended from the electron transporting light-emitting layer to a position at a distance of 20 nm from the electron transporting light-emitting layer was doped with Ir(ppy)₃ by co-evaporation so that Ir(ppy)₃ had a doping concentration of 8% weight.

Next, the electron transporting light-emitting layer, 60 nm in film thickness, was formed by using TbpyB as the electron transporting material, TTF as the donor, and Ir(ppy)₃ as the green light-emitting dopant.

However, a region in the electron transporting light-emitting layer which extended from the cathode to a position at a distance of 40 nm from the cathode was doped with TTF by co-evaporation so that TTF had a doping concentration of 10% by weight, and a region in the electron transporting light-emitting layer which extended from the hole transporting light-emitting layer to a position at a distance of 20 nm from the hole transporting light-emitting layer was doped with Ir(ppy)₃ by co-evaporation so that Ir(ppy)₃ had a doping concentration of 10% by weight.

(Formation of a Red Pixel)

Next, a red light-emitting pixel was formed on a surface of a first electrode by an evaporation method using a shadow mask. With use of DPABDF as the hole transporting material, TCNQF₄ as the acceptor, and tris(1-phenylisoquinoline) iridium (III) T1=2.0 eV (Ir(piq)₃) as a red light-emitting dopant, a hole transporting light-emitting layer 60 nm in film thickness was formed.

However, a region in the hole transporting light-emitting layer which extended from the anode to a position at a distance of 40 nm from the anode was doped with TCNQF₄ by co-evaporation so that TCNQF₄ had a doping concentration of 15% by weight, and a region in the hole transporting light-emitting layer which extended from the electron transporting light-emitting layer to a position at a distance of 20 nm from the electron transporting light-emitting layer was doped with Ir(piq)₃ by co-evaporation so that Ir(piq)₃ had a doping concentration of 5% by weight.

Next, the electron transporting light-emitting layer, 60 nm in film thickness, was formed by using TbpyB as the electron transporting material, TTF as the donor, and Ir(piq)₃ as the red light-emitting dopant.

However, a region in the electron transporting light-emitting layer which extended from the cathode to a position at a distance of 40 nm from the cathode was doped with TTF by co-evaporation so that TTF had a doping concentration of 10% by weight, and a region in the electron transporting light-emitting layer which extended from the hole transporting light-emitting layer to a position at a distance of 20 nm from the hole transporting light-emitting layer was doped with Ir(piq)₃ by co-evaporation so that Ir(piq)₃ had a doping concentration of 3% by weight.

After these three colors of pixels had been formed, second electrodes (to be paired with the first electrodes, respectively) were formed.

First, the substrate on which the pixels had been formed was fixed to a metal evaporation chamber. Next, the substrate was aligned with a second-electrode-forming shadow mask, and a desired pattern of silver (10 nm in thickness) was formed by vacuum evaporation on surfaces of the organic EL layers, whereby translucent second electrodes were formed.

Furthermore, on the translucent second electrodes, an inorganic protecting layer composed SiO₂ 2 μm in thickness was pattern-formed by plasma CVD with use of a shadow mask so as not to be formed in an area where wires from the display are taken out (FPC connection area)

Next, the substrate and a sealing glass over which a UV curing resin adhesive had been applied by a dispenser were joined on top of each other in a dry air environment (with a moisture content of −80° C.), and the UV curing resin adhesive was cured by irradiating it with curing UV light.

At this point in time, an organic EL panel was obtained by joining a polarizer on a side of the substrate through which light produced in the organic EL layers is taken out to the outside.

After that, by mounting an external drive circuit and the like on the organic EL panel, an EL organic display device was obtained.

The organic EL display device thus fabricated was confirmed to emit uniform light at a high luminance (300 cd/m²) without unevenness.

The present invention is not limited to the description of the embodiments above, but may be altered by a skilled person within the scope of the claims. An embodiment based on a proper combination of technical means disclosed in different embodiments is encompassed in the technical scope of the present invention.

Further, the organic electroluminescent element according to the present invention is preferably configured such that the mobility μh (HTM) of holes in the hole transporting material and the mobility μe (ETM) of electrons in the electron transporting material satisfy expressions (1) and (2) as follows:

0.1 μe(ETM)<μh(HTM)<10 μe(ETM) (1); and

0.1 μh(HTM)<μe(ETM)<10 μh(HTM) (2).

According to the foregoing configuration, which satisfies expressions (1) and (2), the balance between holes moving through the hole transporting light-emitting layer and electrons moving through the electron transporting light-emitting layer can be optimized. This makes it possible to achieve high-efficiency emission by improving the rate of recombination of holes and electrons in the interfacial regions between the hole transporting light-emitting layer and the electron transporting light-emitting layer.

Further, the organic electroluminescent element according to the present invention is preferably configured such that the mobility μh (HTM) of holes in the hole transporting material, the mobility μe (HTM) of electrons in the hole transporting material, the mobility μh (ETM) of holes in the electron transporting material, and the mobility μe (ETM) of electrons in the electron transporting material satisfy expressions (3) and (4) as follows:

μh(HTM)>100 μh(ETM) (3); and

μe(ETM)>100 μe(HTM) (4).

According to the foregoing configuration, which satisfies expressions (3) and (4), it is possible to more effectively confine charges in the interfacial regions by using a difference in hole mobility between the hole transporting light-emitting layer and the electron transporting light-emitting layer and a difference in electron mobility between the hole transporting light-emitting layer and the electron transporting light-emitting layer. This makes it possible to achieve high-luminance emission by maintaining the balance between charges even under high luminance.

Further, the organic electroluminescent element according to the present invention is preferably configured such that the mobility μh (HTM) of holes in the hole transporting material, the mobility μe (HTM) of electrons in the hole transporting material, the mobility μh (ETM) of holes in the electron transporting material, and the mobility μe (ETM) of electrons in the electron transporting material satisfy expressions (5) and (6) as follows:

μh(HTM)>100 μe(HTM) (5); and

μe(ETM)>100 μh(ETM) (6).

According to the foregoing configuration, which satisfies expressions (5) and (6), by making a difference between hole mobility and electron mobility in the hole transporting light-emitting layer and a difference between hole mobility and electron mobility in the electron transporting light-emitting layer, breaking down of the balance between holes and electrons can be prevented even when there occurs a difference in decrease between hole mobility and electron mobility due to an aging process. This makes it possible to more effectively prevent a decrease in luminous efficiency and a color shift that is entailed by a movement of a site of recombination.

Further, the organic electroluminescent element according to the present invention is preferably configured such that the first light-emitting dopant and the second light-emitting dopant are identical materials.

According to the foregoing configuration, the light-emitting dopants with which the light-emitting dopant region in the hole transporting light-emitting layer and the light-emitting dopant region in the electron transporting light-emitting layer, i.e., the interfacial regions between the hole transporting light-emitting layer and the electron transporting light-emitting layer have been doped are identical materials.

This makes it possible to form a common wide light-emitting dopant region for each layer in the interfacial regions. This makes it possible to achieve high-efficiency emission by confining charges in the region.

Further, the organic electroluminescent element according to the present invention is preferably configured such that the concentration of the first light-emitting dopant contained in the hole transporting light-emitting layer and the concentration of the second light-emitting dopant contained in the electron transporting light-emitting layer are different from each other. More specifically, it is preferable that the concentration difference be 2% by weight or greater.

This makes it possible to compensate for a shift in charge transfer as caused by charge transfer in the light-emitting dopants and thereby keep the balance between charges. This makes it possible to achieve more high-efficiency emission.

Further, the organic electroluminescent element according to the present invention is preferably configured such that the content of the acceptor in the hole transporting light-emitting layer is higher than the content of the first light-emitting dopant. More specifically, it is preferable that the concentration difference be 7% by weight or greater.

The foregoing configuration allows the hole transporting light-emitting layer to more effectively achieve both high hole injection capability and high luminous efficiency.

Further, the organic electroluminescent element according to the present invention is preferably configured such that the content of the donor in the electron transporting light-emitting layer is higher than the content of the second light-emitting dopant. More specifically, it is preferable that the concentration difference be 4% by weight or greater.

The foregoing configuration allows the electron transporting light-emitting layer to more effectively achieve both high electron injection capability and high luminous efficiency.

Further, the organic electroluminescent element according to the present invention is preferably configured such that the acceptor region is greater in film thickness than the first light-emitting dopant region.

The foregoing configuration allows the hole transporting light-emitting layer to more effectively achieve both high hole transport capability and high luminous efficiency.

Further, the organic electroluminescent element according to the present invention is preferably configured such that the donor region is greater in film thickness than the second light-emitting dopant region.

The foregoing configuration allows the electron transporting light-emitting layer to more effectively achieve both high electron transport capability and high luminous efficiency.

Further, the organic electroluminescent element according to the present invention is preferably configured to further include a region containing neither the acceptor nor the first light-emitting dopant, the region being sandwiched between the acceptor region and the first light-emitting dopant region.

The foregoing configuration prevents direct contact between the light-emitting dopant and the acceptor, thus preventing exciters produced in the light-emitting dopant from being deactivated by energy transfer to the acceptor. This makes it possible to more effectively achieve high luminous efficiency.

Further, the organic electroluminescent element according to the present invention is preferably configured to further include a region containing neither the donor nor the second light-emitting dopant, the region being sandwiched between the donor region and the second light-emitting dopant region.

The foregoing configuration prevents direct contact between the light-emitting dopant and the donor, thus preventing exciters produced in the light-emitting dopant from being deactivated by energy transfer to the donor. This makes it possible to more effectively achieve high luminous efficiency.

### INDUSTRIAL APPLICABILITY

The present invention can be applied to various types of device using organic EL elements, e.g., to display devices such as televisions or to illuminating devices, etc.

### REFERENCE SIGNS LIST

1 Organic EL element
2 Substrate
3 Anode
4 Cathode
5 Hole transporting light-emitting layer
6 Electron transporting light-emitting layer
7 Organic EL layer (organic light-emitting layer)
30 Organic EL panel

1. An organic electroluminescent element comprising:
an anode;
a cathode; and
an organic light-emitting layer sandwiched between the anode and the cathode,
the organic light-emitting layer including a hole transporting light-emitting layer and an electron transporting light-emitting layer,
the hole transporting light-emitting layer being located closer to the anode than the electron transporting light-emitting layer, containing a hole transporting material, and including an acceptor region doped with an acceptor and a first light-emitting dopant region doped with a first light-emitting dopant, the acceptor region being located on that side of the hole transporting light-emitting layer which faces the anode, and the first light-emitting dopant region being located on that side of the hole transporting light-emitting layer which faces the cathode,
the electron transporting light-emitting layer being located closer to the cathode than the hole transporting light-emitting layer, containing an electron transporting material, and including a donor region doped with a donor and a second light-emitting dopant region doped with a second light-emitting dopant, the donor region being located on that side of the electron transporting light-emitting layer which faces the cathode, and the second light-emitting dopant region being located on that side of the electron transporting light-emitting layer which faces the anode.

2. The organic electroluminescent element as set forth in claim 1, wherein the mobility μh (HTM) of holes in the hole transporting material and the mobility μe (ETM) of electrons in the electron transporting material satisfy expressions (1) and (2) as follows:
0.1 μe(ETM)<μh(HTM)<10 μe(ETM) (1); and
0.1 μh(HTM)<μe(ETM)<10 μh(HTM) (2).

3. The organic electroluminescent element as set forth in claim 1, wherein the mobility μh (HTM) of holes in the hole transporting material, the mobility μe (HTM) of electrons in the hole transporting material, the mobility μh (ETM) of holes in the electron transporting material, and the mobility μe (ETM) of electrons in the electron transporting material satisfy expressions (3) and (4) as follows:
μh(HTM)>100 μh(ETM) (3); and
μe(ETM)>100 μe(HTM) (4).

4. The organic electroluminescent element as set forth in claim 1, wherein the mobility μh (HTM) of holes in the hole transporting material, the mobility μe (HTM) of electrons in the hole transporting material, the mobility μh (ETM) of holes in the electron transporting material, and the mobility μe (ETM) of electrons in the electron transporting material satisfy expressions (5) and (6) as follows:
μh(HTM)>100 μe(HTM) (5); and
μe(ETM)>100 μh(ETM) (6).

5. The organic electroluminescent element as set forth in claim 1, wherein the first light-emitting dopant and the second light-emitting dopant are identical materials.

6. The organic electroluminescent element as set forth in claim 1, wherein the concentration of the first light-emitting dopant contained in the hole transporting light-emitting layer and the concentration of the second light-emitting dopant contained in the electron transporting light-emitting layer are different from each other.

7. The organic electroluminescent element as set forth in claim 1, wherein the content of the acceptor in the hole transporting light-emitting layer is higher than the content of the first light-emitting dopant.

8. The organic electroluminescent element as set forth in claim 1, wherein the content of the donor in the electron transporting light-emitting layer is higher than the content of the second light-emitting dopant.

9. The organic electroluminescent element as set forth in claim 1, wherein the acceptor region is greater in film thickness than the first light-emitting dopant region.

10. The organic electroluminescent element as set forth in claim 1, wherein the donor region is greater in film thickness than the second light-emitting dopant region.

11. The organic electroluminescent element as set forth in claim 1 further comprising a region containing neither the acceptor nor the first light-emitting dopant, the region being sandwiched between the acceptor region and the first light-emitting dopant region.

12. The organic electroluminescent element as set forth in claim 1, further comprising a region containing neither the donor nor the second light-emitting dopant, the region being sandwiched between the donor region and the second light-emitting dopant region.

13. An organic electroluminescent display device comprising display means including a thin-transistor substrate and an organic electroluminescent element as set forth in claim 1, the organic electroluminescent element being provided on the thin-transistor substrate.

14. An organic electroluminescent illuminating device comprising an organic electroluminescent element as set forth in claim 1.
